(19) United States
(12) Patent Application Publication
(10) Pub. No.: US 2013/0122649 A1
(43) Pub. Date: May 16, 2013

(54) METHOD FOR MANUFACTURING THIN FILM TRANSISTOR

(71) Applicants: Shengdong Zhang, Shenzhen (CN); Xin He, Shenzhen (CN); Yi Wang, Shenzhen (CN); Dedong Han, Shenzhen (CN); Ruqi Han, Shenzhen (CN)

(72) Inventors: Shengdong Zhang, Shenzhen (CN); Xin He, Shenzhen (CN); Yi Wang, Shenzhen (CN); Dedong Han, Shenzhen (CN); Ruqi Han, Shenzhen (CN)

(73) Assignee: Peking University Shenzhen Graduate School, Shenzhen (CN)

(21) Appl. No.: 13/376,833

(22) PCT Filed: Jun. 13, 2011
(86) PCT No.: PCT/CN11/75649

§ 371 Date: Jan. 22, 2013

(30) Foreign Application Priority Data
Jan. 18, 2011 (CN) 201110020661.7

(51) Int. Cl. H01L 29/66

(52) U.S. Cl. CPC H01L 29/66742
USPC 438/104

(57) ABSTRACT

Disclosed is a method for manufacturing a metal oxide thin film transistor. According to the method, an active layer having a high carrier concentration is formed, and then a channel region is oxidized by plasma having oxidbillity so that the channel region has a low carrier concentration while a source region and a drain region have high carrier concentrations. In addition, the threshold voltage of the transistor is controlled by the conditions under which the channel region of the transistor is subsequently oxidized by plasma having oxidbillity at a low temperature. Therefore, the controllability of the characteristics of the transistor is improved significantly, and the manufacturing process is simplified.

### FIELD OF THE INVENTION

The present invention relates to a method for manufacturing a thin film transistor, especially to a method for manufacturing a metal oxide semiconductor thin film transistor.

### BACKGROUND OF THE INVENTION

Thin film transistors are used as switching elements or integrated elements of peripheral driving circuits in various display devices. Presently, widely used thin film transistors mainly include amorphous silicon thin film transistors and polycrystalline silicon thin film transistors. However, since the amorphous silicon thin film transistors have low mobility and easy performance degradation, the applications in the pixel driving of an OLED and in the integration of peripheral driving circuits of a LCD and OLED are limited. Moreover, the manufacturing of the polycrystalline silicon thin film transistors needs a high temperature, the manufacturing cost is high, and the performance uniformity of the polycrystalline silicon thin film transistors is poor. Thus, the polycrystalline silicon thin film transistors are not suitable to the large-size panel displays. Therefore, for developments of the large-size panel displays, it is needed to develop advancer thin film transistors. Currently, the new developing thin film transistors mainly include metal oxide semiconductor thin film transistors represented by the zinc oxide semiconductor thin film transistors, microcrystalline thin film transistors and organic semiconductor thin film transistors.

The zinc oxide based and indium oxide based thin film transistors have low manufacturing process temperatures, low manufacturing cost, high carrier mobility, and uniform and stable performance. That is, the zinc oxide based and indium oxide based thin film transistors have the advantages both of the amorphous silicon thin film transistors and of the polycrystalline silicon thin film transistors, and are large-size microelectronic device having a good prospect. However, the zinc oxide based thin film transistors have such disadvantages that the formed semiconductor channel layer tend to have a very high carrier concentration, so that the threshold voltage of the transistors is very low and even negative (for the N-typed transistors). That is, when the gate is in the state of zero bias, the transistor cannot be turned off sufficiently. If the channel layer is fabricated into a high-resistance layer having a low concentration, the parasitic resistance of source and drain regions will be increased accordingly. Therefore, there is needed to add a metal layer having low-resistance, resulting in a more complicated process.

### SUMMARY OF THE INVENTION

The main technical problem to be solved by the present invention is to provide a method for manufacturing a metal oxide thin film transistor. While the transistor has a high carrier concentration in source and drain regions of an active layer, it is ensured that a channel region of the active layer has a low carrier concentration at a gate bias of zero.

According to one aspect of the present invention, there is provided a method for manufacturing a thin film transistor, which comprises:

a step of forming a gate electrode, wherein a metal or transparent conductive film is formed on a substrate to be the gate electrode;

a step of forming gate dielectric layer, wherein the gate dielectric layer covering the gate electrode is formed on the substrate;

a step of forming and processing an active region, wherein a metal oxide semiconductor layer having a high carrier concentration is formed on the gate dielectric layer, the metal oxide semiconductor layer is processed to form the active region including a source region, a drain region and a channel region, and the channel region is oxidized by plasma having oxidbillity at a temperature which is lower than the highest temperature that the substrate can stand; and

a step of leading electrodes, wherein electrode leads for the source region, drain region and gate electrode are formed.

In an embodiment, the step of forming and processing an active region further comprises performing a thermal treatment on the metal oxide semiconductor layer in an oxygen-free environment before the metal oxide semiconductor layer is processed to form the active region.

In an embodiment, in the step of forming and processing an active region, the metal oxide semiconductor layer is directly coated with a photoresist layer, subjected to photolithography so that the channel region in the metal oxide semiconductor layer is exposed, and then oxidized by plasma having oxidbillity at a temperature of 25-180° C.

In an embodiment, in the step of forming and processing an active region, a dielectric protection layer is formed over the metal oxide semiconductor layer before the photoresist layer is coated thereon, subjected to photolithography and etching so that the channel region in the metal oxide semiconductor layer is exposed, and then oxidized by oxygen plasma having oxidbillity at a temperature which is lower than the highest temperature that the substrate can stand.

In the present invention, the metal oxide semiconductor layer having a high carrier concentration is formed so that the source and drain regions of the thin film transistor have high carrier concentrations. The channel region of the transistor is oxidized by plasma having oxidbillity at a temperature which is lower than the highest temperature the substrate can stand, so that the channel region has a low carrier concentration at a gate bias of zero while source and drain regions of the thin film transistor have high carrier concentrations. In addition, the threshold voltage of the transistor is controlled by the conditions under which the channel region of the transistor is subsequently oxidized by plasma having oxidbillity at a low temperature. Thus, the controllability of the characteristics of the transistor is improved significantly. According to the conventional manufacturing method, the voltage ratio of the oxygen to the argon in the sputtering atmosphere is adjusted so as to control the threshold voltage. Since the threshold voltage is very sensitive to the voltage ratio, the controllability is poor.

Further, the oxygen plasma has a very high activity, and the channel region can be oxidized by the oxygen plasma even at room temperature. Thus, it is unnecessary that the channel region is oxidized after being heated to a certain temperature so that the temperature at which the transistor is manufactured can be reduced significantly.

### BRIEF DESCRIPTION OF THE DRAWINGS

FIG. 1 is a schematic cross-sectional view of a thin film transistor according to an embodiment of the present invention;

FIGS. 2-8 show successively the main steps of manufacturing the thin film transistor according to an embodiment of the present invention, wherein:

FIG. 2 shows a step of forming a gate electrode;

FIG. 3 shows a step of forming a gate dielectric layer;

FIG. 4 shows a step of forming and thermally treating a metal oxide semiconductor layer;

FIG. 5 shows a step of treating the metal oxide semiconductor layer to form an active layer;

FIG. 6 shows a step of coating photoresist, patterning the photoresist and then oxidizing the channel region;

FIG. 7 shows a step of depositing a passivation layer and forming contact holes;

FIG. 8 shows a step of forming leads of the source, drain and gate electrodes;

FIGS. 9-16 show successively the main steps of manufacturing the thin film transistor according to another embodiment of the present invention, wherein:

FIG. 9 shows a step of forming a gate electrode;

FIG. 10 shows a step of forming a gate dielectric layer;

FIG. 11 shows a step of forming and thermally treating a metal oxide semiconductor layer;

FIG. 12 shows a step of depositing a dielectric protection layer and patterning the metal oxide semiconductor layer and dielectric protection layer;

FIG. 13 shows a step of patterning the dielectric protection layer so that the channel region is exposed;

FIG. 14 shows a step of oxidizing the channel region by oxygen plasma;

FIG. 15 shows a step of depositing a passivation layer and forming contact holes; and

FIG. 16 shows a step of forming leads of the source, drain and gate electrodes.

### DESCRIPTION OF THE PREFERRED EMBODIMENTS

In the embodiments of the present invention, an active layer of a thin film transistor is formed from a metal oxide semiconductor layer having a high carrier concentration. After the active layer is formed, source and drain regions are protected and a channel region is exposed to the plasma atmosphere having oxidative function, such as the oxygen plasma atmosphere. Thus, the oxygen vacancy concentration in the channel region is reduced significantly and the channel region becomes a high-resistance layer having a low carrier concentration.

Hereinafter, the present invention will be described in detail by means of the embodiments thereof and with reference to the drawings.

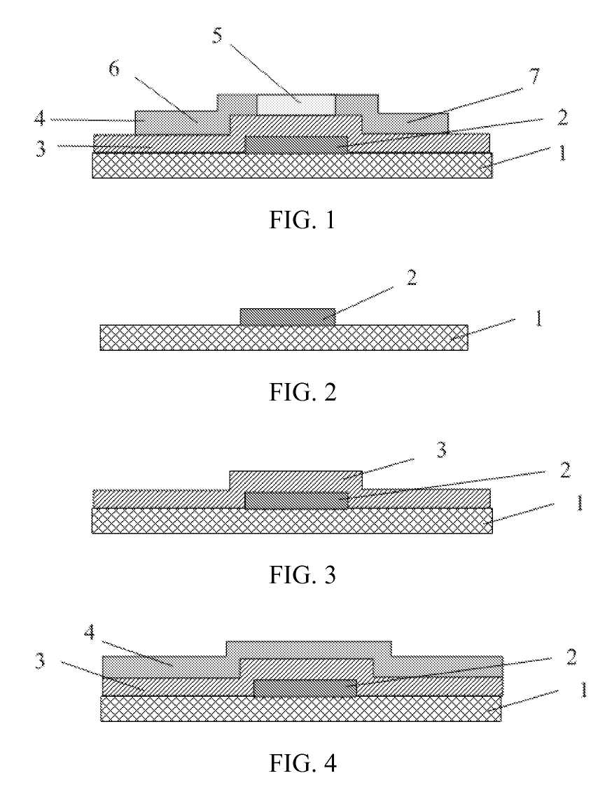

With reference to FIG. 1, a sectional view for a thin film transistor in an embodiment is shown. The thin film transistor comprises a gate electrode 2, a gate dielectric layer 3 and a metal oxide semiconductor layer 4. The metal oxide semiconductor layer 4 is composed of a channel region 5, a source region 6 and a drain region 7. The gate electrode 2 is formed on a substrate 1, and the gate dielectric layer 3 is formed on the substrate 1 and gate electrode 2 and covers the gate electrode 2. The metal oxide semiconductor layer 4 is formed over the gate dielectric layer 3. The channel region 5 forms a central portion of the metal oxide semiconductor layer 4 and is arranged on the gate dielectric layer 3 covering the gate electrode 2. The source region 6 and drain region 7 form two end portions of the metal oxide semiconductor layer 4. The source region 6 and drain region 7 are arranged on the gate dielectric layer 3 and connected with the channel region 5, respectively.

In an example, the gate electrode 2 may be formed from metal material, such as chromium, molybdenum, titanium, aluminium or the like, and may be formed by, for example, magnetron sputtering or thermal evaporation. In another example, the gate electrode 2 may be formed into a transparent conductive film, such as tin indium oxide (ITO) or aluminum zinc oxide (AZO) and may be formed by, for example, magnetron sputtering. Generally, the gate electrode 2 has a thickness in the range of 100 to 300 nm. The gate dielectric layer 3 is formed from insulating dielectric, such as silicon nitride, silicon oxide or the like, and may be formed by plasma enhanced chemical vapor deposition (PECVD) or magnetron sputtering. In another example, the gate dielectric layer 3 may be formed from metal oxide, such as aluminum oxide, tantalum oxide, hafnium oxide or the like, and may be formed by, for example, magnetron sputtering. Generally, the gate dielectric layer 3 has a thickness in the range of 100 to 400 nm. The metal oxide semiconductor layer 4 is formed from amorphous or polycrystalline metal oxide semiconductor material, such as zinc oxide based or indium oxide based film, and may be formed by, for example, magnetron sputtering. The metal oxide semiconductor layer 4 has a thickness in the range of 50 to 200 nm. Since the channel region 5 forms a central portion of the active layer 4, in the case where the channel region 5 is not biased, that is, the voltage of the gate electrode is zero, the channel region 5 has a very low carrier concentration and thus is in a high impedance state. The source region 6 and the drain region 7 are arranged at ends of the active layer 4, having a high carrier concentration and being in a low impedance state.

### Embodiment 1

A method for manufacturing the thin film transistor according to the present embodiment is shown in FIGS. 2-8 and comprises the following steps.

11) As shown in FIG. 2, a metal film having a thickness of 100-300 nm is formed on a surface (such as a front surface) of the substrate 1. The metal film may be formed by magnetron sputtering and may be formed from chromium, molybdenum, titanium, aluminium or the like. Then, the metal film is processed accordingly, for example, subjected to photolithography and etching, so that the gate electrode 2 is formed. In the present embodiment, the substrate 1 may be resistant to a high temperature, such as a glass substrate, or may be not resistant to a high temperature, such as a plastic substrate. For ease of description, the surface of the substrate on which the thin film transistor is manufactured is called a front surface.

12) As shown in FIG. 3, an insulating film having a thickness of 100-400 nm is formed on the front surface of the substrate 1. The insulating film may be formed from insulating dielectric, such as silicon nitride, silicon oxide or the like, and may be formed by plasma enhanced chemical vapor deposition (PECVD). The insulating film covers the gate electrode 2 as the gate dielectric layer 3.

13) As shown in FIG. 4, the metal oxide semiconductor layer 4 is formed over the gate dielectric layer 3 and has a thickness of 50 to 200 nm. The metal oxide semiconductor layer 4 is formed from amorphous or polycrystalline metal oxide semiconductor material, such as zinc oxide based or indium oxide based film, and may be deposited by, for example, magnetron sputtering. In the case of the indium gallium zinc oxide (IGZO), the target is composed of the mixture of gallium oxide, indium oxide and zinc oxide. The mole ratio of gallium oxide to indium oxide to zinc oxide is X: Y: Z, wherein X>40%, Y>40, and Z<20%, and preferably equal to 3:3:1. In the case of indium oxide, used is a ceramic target of indium oxide, the purity of which is equal to or higher than 99.99%. Sputtering pressure is in the range of 0.5˜2.5 Pa, and pure Argon is used as the sputtering gas. At this time, since a number of oxygen vacancies are generated in the entirely formed metal oxide semiconductor layer 4, the metal oxide semiconductor layer 4 functions as a low-resistance material having a high carrier concentration. If a lower resistance material is needed, a thermal process may be performed on the metal oxide semiconductor layer 4 in an oxygen-free environment. For example, the thermal process may be conducted in hydrogen, nitrogen or vacuum and under a temperature lower than the highest temperature that the substrate 1 can stand.

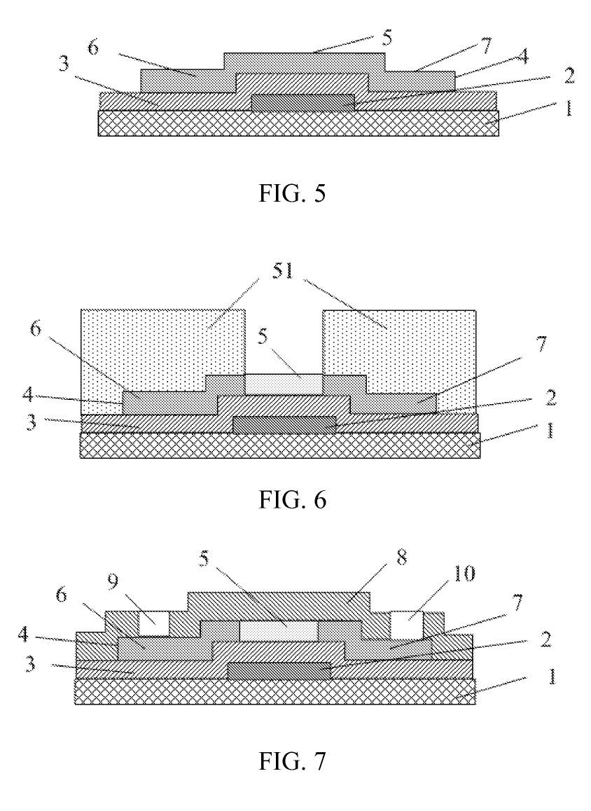

14) As shown in FIG. 5, the metal oxide semiconductor layer 4 is processed accordingly so that an active region is formed. The active region comprises the source region 6, the drain region 7 and the channel region 5. The metal oxide semiconductor layer 4 is processed by, for example, photolithography and etching.

15) As shown in FIG. 6, the processed metal oxide semiconductor layer 4 is coated by a photoresist layer and then subjected to photolithography, so that the channel region 5 in the metal oxide semiconductor layer 4 is exposed and the rest is protected by the photoresist layer. Next, the channel region is oxidized by the oxygen plasma for 5˜60 minutes at low temperatures. Since the channel region 5 is exposed and oxidized by the oxygen plasma, the concentration of oxygen vacancies in the channel region 5 is reduced and the channel region 5 turns to have a low carrier concentration. The photoresist layer in the present embodiment may be positive or negative. In the present embodiment, since the oxygen plasma is selected for oxidization, the oxidization may be conducted at low temperatures, such as 25-180° C. The temperature limit within which the oxidization is conducted cannot be higher than the highest temperature that the photoresist and the substrate 1 can stand.

16) As shown in FIG. 7, a layer of silicon nitride 8 is deposited by plasma enhanced chemical vapor deposition (PECVD) or magnetron sputtering, and photolithography and etching processes are performed to form contact holes 9 and 10 of the electrode.

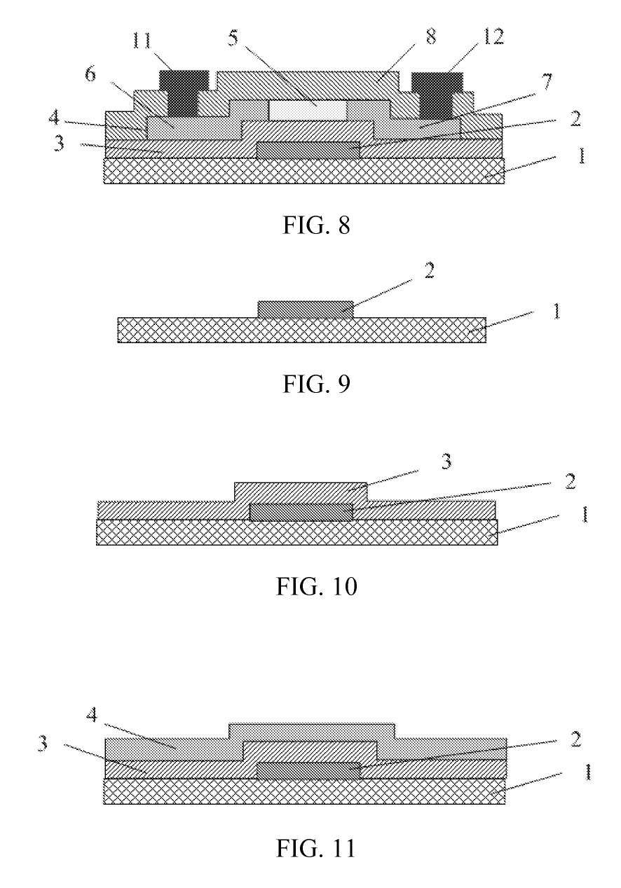

17) As shown in FIG. 8, a layer of aluminum film having a thickness of 100-300 nm is deposited by magnetron sputtering, and then subjected to photolithography and etching to form metal lead electrodes and interconnections 11 and 12 of the electrodes of the thin film transistor.

In the present embodiment, the channel region 5 is oxidized by the oxygen plasma at a low temperature. The activity of the free radicals in the plasma is much higher than that of the corresponding gas. For example, the activity of the oxygen free radicals in the oxygen plasma is much higher than that of the oxygen molecules. Thus, where the channel region 5 is oxidized by the oxygen plasma, the channel region 5 can be substantially oxidized even at a low temperature and the concentration of oxygen vacancies is reduced. Therefore, the substrate 1 can be formed not only from materials which are resistant to high temperatures, but also from materials for low temperatures.

### Embodiment 2

Since the channel region 5 is oxidized by the oxygen plasma at a low temperature in the present invention, it is unnecessary to form a dielectric protection layer, simplifying the manufacturing process of transistors. However, the oxygen plasma has some effect on the protective photoresist layer. Although the advantage of using the photoresist layer as a protection layer lies in that the manufacturing process is simple, a portion of the photoresist may be destroyed by the oxygen plasma during the process, and thus the source and drain regions cannot be entirely protected from oxidation. Accordingly, for precisely protecting the source and drain regions, a dielectric protection layer may be formed and the formed dielectric protection layer can be subjected to high temperatures for the subsequent manufacturing process. The manufacturing steps are as follows.

21) As shown in FIG. 9, a metal film having a thickness of 100-300 nm is formed on the front surface of the substrate 1. The metal film may be formed from chromium, molybdenum, titanium, aluminium or the like, and may be formed by magnetron sputtering. Then, the metal film is subjected to photolithography and etching so as to form the gate electrode 2. In the present embodiment, the substrate 1 may be resistant to high temperatures, or may be used at low temperatures.

22) As shown in FIG. 10, an insulating film having a thickness of 100-400 nm is formed on the front surface of the substrate 1 by plasma enhanced chemical vapor deposition (PECVD). The insulating film may be formed from insulating dielectric, such as silicon nitride, silicon oxide or the like, covering the gate electrode 2 as the gate dielectric layer 3.

23) As shown in FIG. 11, a metal oxide semiconductor layer 4 is deposited over the gate dielectric layer 3 by radio magnetron sputtering and has a thickness of 50 to 200 nm. The metal oxide semiconductor layer 4 is formed from amorphous or polycrystalline metal oxide semiconductor material, such as zinc oxide based or indium oxide based film. In the case of the IGZO, the target is composed of the mixture of gallium oxide, indium oxide and zinc oxide. The mole ratio of gallium oxide to indium oxide to zinc oxide is X: Y: Z, wherein X>40%, Y>40, and Z<20%, and preferably equal to 3:3:1. In the case of indium oxide, used is a ceramic target of indium oxide, the purity of which is equal to or higher than 99.99%. Sputtering pressure is in the range of 0.5˜2.5 Pa, and pure Argon is used as the sputtering gas. At this time, since a number of oxygen vacancies are generated in the entirely formed metal oxide semiconductor layer 4, the metal oxide semiconductor layer 4 functions as a low-resistance material having a high carrier concentration. If a lower resistance material is needed, a thermal process may be performed on the metal oxide semiconductor layer 4 in an oxygen-free environment. For example, the thermal process may be conducted in hydrogen, nitrogen or vacuum and under a temperature lower than the highest temperature that the substrate 1 can stand.

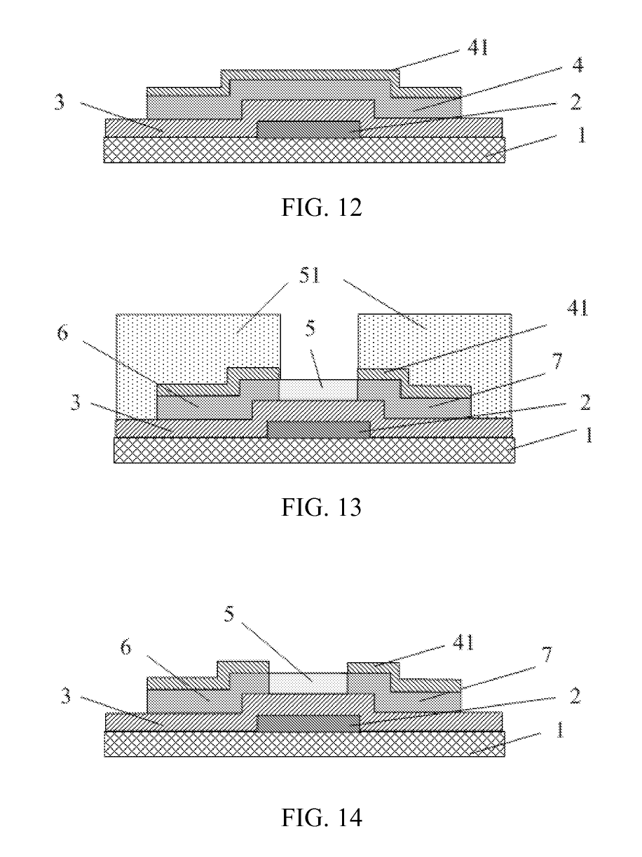

24) As shown in FIG. 12, a dielectric protection film is formed over the metal oxide semiconductor layer 4 processed by the step 23. The dielectric protection film may be formed from silicon oxide or silicon nitride by plasma enhanced chemical vapor deposition (PECVD) or magnetron sputtering, and has a thickness of 20-80 nm. The dielectric protection film and the metal oxide semiconductor layer 4 are subjected to photolithography and etching so that the active region protection layer 41 and an active region of the transistor are formed. The active region comprises the source region 6, the drain region 7 and the channel region 5.

25) As shown in FIGS. 13 and 14, the active region protection layer 41 after being subjected to photolithography and etching is coated by a photoresist layer. The photoresist layer in the present embodiment may be positive or negative. Then, the photoresist layer is subjected to photolithography and etching, so that the channel region 5 in the metal oxide semiconductor layer 4 is exposed and the rest is protected by the dielectric protection layer. Next, the channel region is oxidized by the oxygen plasma for 5˜60 minutes at low temperatures. Since the channel region 5 is exposed and oxidized by the oxygen plasma, the concentration of oxygen vacancies in the channel region 5 is reduced and the channel region 5 turns to have a low carrier concentration. In the present embodiment, since the oxygen plasma is selected for oxidization, the oxidization may be conducted at a low temperature, such as 25-180° C. It should be noted that, prior to the oxidation, if the photoresist on the dielectric layer of the source and drain regions is retained, the highest temperature at which the oxidization can be conducted should be lower than that the substrate 1 and the photoresist can stand; and if the photoresist has been removed, the highest temperature at which the oxidization is conducted should be lower than the highest temperature the substrate 1 can stand.

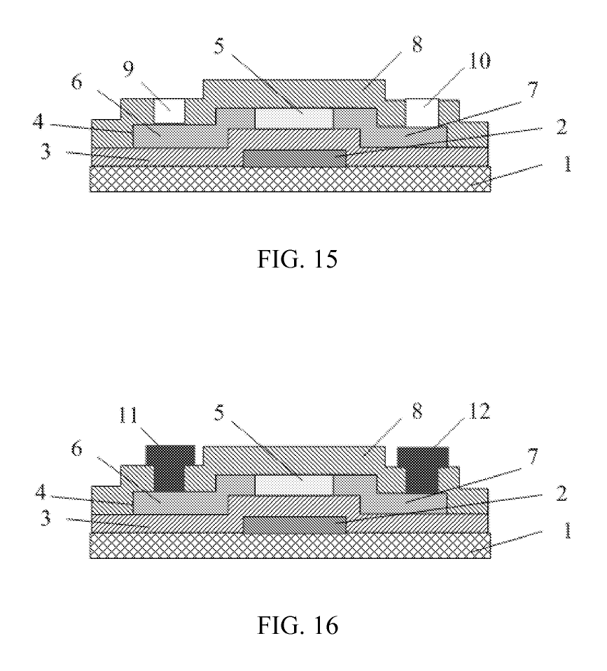

26) As shown in FIG. 15, a layer of silicon nitride 8 having a thickness of 100˜300 nm is deposited by plasma enhanced chemical vapor deposition (PECVD) or magnetron sputtering. Then, the photolithography and etching processes are performed to form contact holes 9 and 10 of the electrode.

27) As shown in FIG. 16, a layer of aluminum film having a thickness of 100˜300 nm is deposited by magnetron sputtering, and then subjected to photolithography and etching to form metal lead electrodes and interconnections 11 and 12 of the electrodes of the thin film transistor.

While the transistor manufactured by the methods according to the embodiments of the present invention has a high carrier concentration in the source and drain regions, the channel region has a low carrier concentration at a gate bias of zero. In the meantime, since the oxygen plasma has a very strong oxidbillity even at low temperatures, during the process in which the channel region is oxidized, the channel region can be substantially oxidized by the oxygen plasma at low temperatures (such as 25-180). Therefore, the cheap substrate for low temperatures (such as a plastic substrate) may be selected for the substrate in the present invention and the process may be conducted at low temperatures. As long as the temperature is not higher than the highest temperature that the substrate can stand, the corresponding process can be conducted. Thus, the manufacturing costs of the thin film transistor are reduced in view of the materials and process.

It is noted that the present invention is not limited to the above embodiments. Without departing the concept of the present invention, simple deduction or substitution made by the skilled in the art should be within the protection scope of the present invention.

1. A method for manufacturing a thin film transistor, comprising:
a step of forming a gate electrode, wherein a metal or transparent conductive film is formed on a substrate to be the gate electrode;
a step of forming gate dielectric layer, wherein the gate dielectric layer covering the gate electrode is formed on the substrate;
a step of forming and processing an active region, wherein a metal oxide semiconductor layer having a high carrier concentration is formed on the gate dielectric layer, the metal oxide semiconductor layer is processed to form the active region including a source region, a drain region and a channel region, and the channel region is oxidized by plasma having oxidbillity at a temperature which is lower than the highest temperature that the substrate can stand; and
a step of leading electrodes, wherein electrode leads for the source region, drain region and gate electrode are formed.

2. The method according to claim 1, wherein the plasma having oxidbillity is oxygen plasma.

3. The method according to claim 1, wherein the step of forming and processing an active region further comprises performing a thermal treatment on the metal oxide semiconductor layer in an oxygen-free environment before the metal oxide semiconductor layer is processed to form the active region.

4. The method according to claim 1, wherein, in the step of forming and processing an active region, the metal oxide semiconductor layer is directly coated with a photoresist layer, subjected to photolithography so that the channel region in the metal oxide semiconductor layer is exposed, and then oxidized by plasma having oxidbillity at a temperature of 25-180° C.

5. The method according to claim 1, wherein, in the step of forming and processing an active region, a dielectric protection layer is formed over the metal oxide semiconductor layer before the photoresist layer is coated thereon, subjected to photolithography and etching so that the channel region in the metal oxide semiconductor layer is exposed, and then oxidized by oxygen plasma having oxidbillity at a temperature which is lower than the highest temperature that the substrate can stand.

6. The method according to claim 1, wherein the substrate is high temperature resistance or is not high temperature resistance.

7. The method according to claim 1, wherein the metal oxide semiconductor layer is formed from zinc oxide based materials or indium oxide based materials.
